(19) United States
(12) Patent Application Publication
(10) Pub. No.: US 2025/0261480 A1
(43) Pub. Date: Aug. 14, 2025

(54) LIGHT EMITTING ELEMENT, METHOD OF MANUFACTURING LIGHT EMITTING ELEMENT, AND DISPLAY DEVICE INCLUDING LIGHT EMITTING ELEMENT

(71) Applicant: Samsung Display Co., LTD., Yongin-si (KR)

(72) Inventors: Kwan Jae LEE, Yongin-si (KR); Jun Youn KIM, Yongin-si (KR); Young Chul SIM, Yongin-si (KR); Sang Tae LEE, Yongin-si (KR)

(21) Appl. No.: 18/963,113

(22) Filed: Nov. 27, 2024

(30) Foreign Application Priority Data
Feb. 14, 2024 (KR) 10-2024-0021317

(51) Int. Cl. H01L 33/06; H01L 25/075; H01L 33/00; H01L 33/20; H01L 33/32

(52) U.S. Cl. CPC H10H 20/812; H01L 25/0753; H10H 20/0137; H10H 20/819; H10H 20/825

(57) ABSTRACT

According to an embodiment of the disclosure, a light emitting element may include a first semiconductor layer, an auxiliary layer on the first semiconductor layer, an active layer on the auxiliary layer, and a second semiconductor layer on the active layer. The auxiliary layer may include a first auxiliary layer surface adjacent to the first semiconductor layer and a second auxiliary layer surface which is a side surface adjacent to the first auxiliary layer surface, the active layer may include a well layer and a barrier layer, the auxiliary layer may have a superlattice structure, and the well layer may be on the first auxiliary layer surface without being on the second auxiliary layer surface of the auxiliary layer.

### CROSS-REFERENCE TO RELATED APPLICATION

The present application claims priority to and the benefit of Korean Patent Application No. 10-2024-0021317, filed on Feb. 14, 2024, in the Korean Intellectual Property Office, the entire content of which is hereby incorporated by reference.

### BACKGROUND

### 1. Field

Embodiments of the present disclosure relate to a light emitting element, a method of manufacturing the light emitting element, and a display device including the light emitting element.

### 2. Description of the Related Art

As information technology develops, the importance of a display device, which is a connection medium between a user and information, is increasing. The display device may include a light emitting element that is on a micro scale or a nano scale, and the light emitting element may include a p-type semiconductor, an n-type semiconductor, and an active layer including a quantum well structure.

The display device should have various suitable operation characteristics. For example, in order to improve light output efficiency of the display device, color purity of the display device should be improved.

### SUMMARY

An aspect of embodiments of the disclosure provides a light emitting element capable of increasing color purity, a method of manufacturing the light emitting element, and a display device including the light emitting element.

However, an object of the disclosure is not limited to the above-described objects, and may be expanded suitably and variously without departing from the spirit and scope of the disclosure.

According to an embodiment of the disclosure, a light emitting element may include a first semiconductor layer, an auxiliary layer on the first semiconductor layer, an active layer on the auxiliary layer, and a second semiconductor layer on the active layer. The auxiliary layer may include a first auxiliary layer surface adjacent to the first semiconductor layer and a second auxiliary layer surface which is a side surface adjacent to the first auxiliary layer surface, the active layer may include a well layer and a barrier layer, the auxiliary layer may have a superlattice structure, and the well layer may be on the first auxiliary layer surface without being on (e.g., without physically contacting) the second auxiliary layer surface of the auxiliary layer.

According to an embodiment, the second auxiliary layer surface may be an inclined surface.

According to an embodiment, the first auxiliary layer surface and the well layer may contact each other, and the second auxiliary layer surface and the well layer may not contact each other (e.g., without physically contacting each other).

According to an embodiment, the auxiliary layer may have a structure in which InGaN and GaN are alternately stacked.

According to an embodiment, the first semiconductor layer may include a first surface and a second surface which is a side surface adjacent to the first surface, the first surface may be a c-plane, and the second surface may be a semipolar surface.

According to an embodiment, the auxiliary layer may entirely cover the first surface and the second surface.

According to an embodiment, the active layer may further include a cap layer on the well layer, and the cap layer may include one or more selected from AlN and AlₓGa_{y}N_{z} (0≤x≤1, 0≤y≤1, 0≤z≤1, 0≤x+y+z≤1).

According to an embodiment, in the AlₓGa_{y}N_{z} (0≤x≤1, 0≤y≤1, 0≤z≤1, 0≤x+y+z≤1), Al may have a composition of 25 mol % or more and less than 100 mol % with respect to Ga.

According to an embodiment, the cap layer may have a thickness of 0.5 nm to 2.5 nm.

According to an embodiment, the cap layer may have the same diameter as the well layer.

According to an embodiment, the light emitting element may have a truncated pyramid shape.

According to an embodiment of the disclosure, a method of manufacturing a light emitting element may include forming an insulating layer (e.g., an electrically insulating layer) on a base substrate, forming a first semiconductor layer on the base substrate, forming an auxiliary layer on the first semiconductor layer, forming an active layer on the auxiliary layer, and forming a second semiconductor layer on the active layer. Forming the auxiliary layer on the first semiconductor layer may include forming the auxiliary layer having a first auxiliary layer surface adjacent to the first semiconductor layer and a second auxiliary layer surface which is a side surface adjacent to the first auxiliary layer surface, forming the active layer on the auxiliary layer may include forming the active layer including a well layer and a barrier layer, the auxiliary layer may have a superlattice, and the well layer may be on the first auxiliary layer surface without being on the second auxiliary layer surface of the auxiliary layer.

According to an embodiment, forming the first semiconductor layer on the base substrate may include forming the first semiconductor layer having a first surface and a second surface adjacent to the first surface, the first surface may be a c-plane, the second surface may be a semipolar surface, and the second auxiliary layer surface may be an inclined surface with respect to the first auxiliary layer surface (e.g., the second auxiliary layer surface may be inclined with respect to the first auxiliary layer surface).

According to an embodiment, forming the well layer may include forming a base well layer including a first portion and a second portion on the auxiliary layer, and etching the second portion, the first portion may contact (e.g., physically contact) the first auxiliary layer surface, the second portion may contact (e.g., physically contact) the second auxiliary layer surface, the second auxiliary layer surface may be an inclined surface with respect to the first auxiliary layer surface (e.g., the second auxiliary layer surface may be inclined with respect to the first auxiliary layer surface), the second portion may be etched, and the well layer may not contact the second auxiliary layer surface.

According to an embodiment, the second portion may be etched by an etching gas including nitrogen (N₂) gas and hydrogen (H₂) gas, the hydrogen gas may flow at a flow rate of 5% or more and less than 25% with respect to a total flow rate of the nitrogen gas and the hydrogen gas, and the second portion may be removed by an in-situ process.

According to an embodiment of the disclosure, a display device may include a base layer, and a light emitting element on the base layer. The light emitting element may include a first semiconductor layer, an auxiliary layer on the first semiconductor layer, an active layer on the auxiliary layer, and a second semiconductor layer on the active layer, the auxiliary layer may include a first auxiliary layer surface adjacent to the first semiconductor layer and a second auxiliary layer surface which is a side surface adjacent to the first auxiliary layer surface, the active layer may include a well layer and a barrier layer, the auxiliary layer may have a superlattice structure, and the well layer may be on the first auxiliary layer surface without being on the second auxiliary layer surface of the auxiliary layer.

According to an embodiment, the first semiconductor layer may include a first surface and a second surface adjacent to the first surface, the first side may be a c-plane, a second surface may be a semipolar surface and a non-etched surface, the second auxiliary layer surface may be an inclined surface, and the auxiliary layer may entirely cover the first surface and the second surface.

According to an embodiment, the active layer of the light emitting element may further include a cap layer on the well layer, and the cap layer may include one or more selected from AlN and AlₓGa_{y}N_{z} (0≤x≤1, 0≤y≤1, 0≤z≤1, 0≤x+y+z≤1).

According to an embodiment, the display device may include a pixel, the pixel may include a first sub-pixel, a second sub-pixel, and a third sub-pixel, and the first sub-pixel, the second sub-pixel, and the third sub-pixel may have different diameters, respectively.

According to an embodiment, the well layer may include well layers, the barrier layer may include barrier layers, and the well layers and the barrier layers may be alternately provided.

According to an embodiment of the disclosure, a light emitting element capable of increasing color purity, a method of manufacturing the light emitting element, and a display device including the light emitting element may be provided.

However, an effect of embodiments of the disclosure is not limited to the above-described effect, and may be suitably expanded variously without departing from the spirit and scope of the disclosure.

### BRIEF DESCRIPTION OF THE DRAWINGS

The above and other features of embodiments of the disclosure will become more apparent by describing in further detail embodiments thereof with reference to the accompanying drawings, in which:

FIG. 1 is a schematic plan view illustrating a display device according to an embodiment;

FIGS. 2-4 are schematic plan views of an embodiment of a pixel shown in FIG. 1;

FIG. 5 is a schematic cross-sectional view of a display device according to an embodiment;

FIG. 6 is a schematic plan view of a first semiconductor layer;

FIG. 7 is a schematic cross-sectional view of a display device according to an embodiment;

FIG. 8 is a schematic cross-sectional view of a multi-quantum well layer according to an embodiment;

FIG. 9 is a flowchart schematically illustrating a method of manufacturing a light emitting element; and

FIGS. 10-18 are schematic cross-sectional views illustrating a method of manufacturing a light emitting element.

### DETAILED DESCRIPTION

The subject matter of the disclosure may be modified in various suitable manners and have various suitable forms. Therefore, example embodiments will be illustrated in the drawings and will be described in more detail in the specification. However, it should be understood that the disclosure is not intended to be limited to the disclosed specific forms, and the disclosure includes all modifications, equivalents, and substitutions within the spirit and technical scope of the disclosure.

Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component. In the following description, the singular expressions include plural expressions unless the context clearly dictates otherwise.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In embodiments, a case where a portion of a layer, a layer, an area, a plate, or the like is referred to as being “on” another portion, it includes not only a case where the portion is “directly on” another portion, but also a case where there is further another portion between the portion and the other portion. In embodiments, in the present specification, when a portion of a layer, a layer, an area, a plate, or the like is formed on another portion, a forming direction is not limited to an upper direction but includes forming the portion on a side surface or in a lower direction. In embodiments, when a portion of a layer, a layer, an area, a plate, or the like is formed “under” another portion, this includes not only a case where the portion is “directly beneath” another portion but also a case where there is further another portion between the portion and the other portion.

Embodiments of the present disclosure relate to a light emitting element, a method of manufacturing the light emitting element, and a display device including the light emitting element. Hereinafter, a light emitting element, a method of manufacturing the light emitting element, and a display device including the light emitting element according to an embodiment are described with reference to the accompanying drawings.

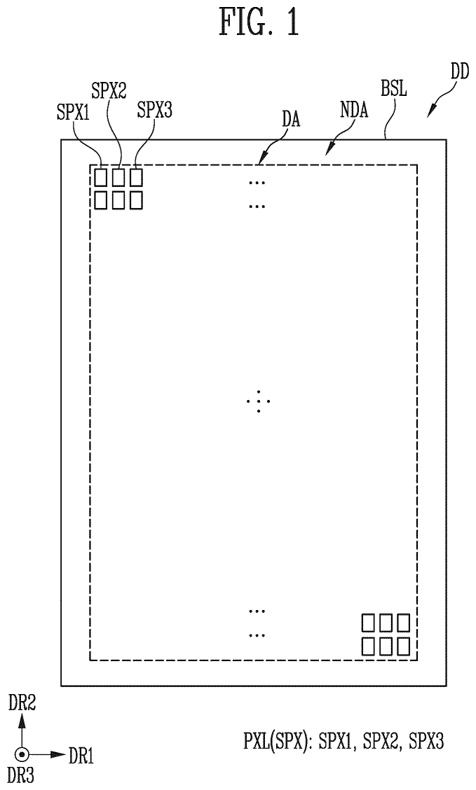

First, a display device DD is described with reference to FIGS. 1 to 4.

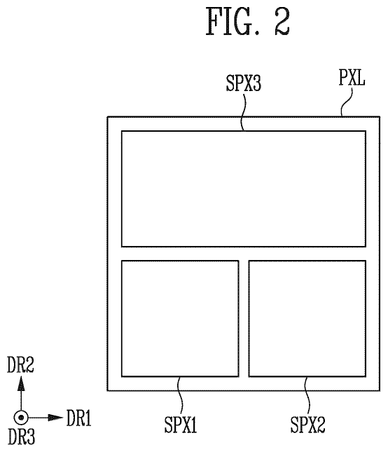

FIG. 1 is a schematic plan view illustrating a display device according to an embodiment. FIGS. 2-4 are schematic plan views of an embodiment of a pixel shown in FIG. 1.

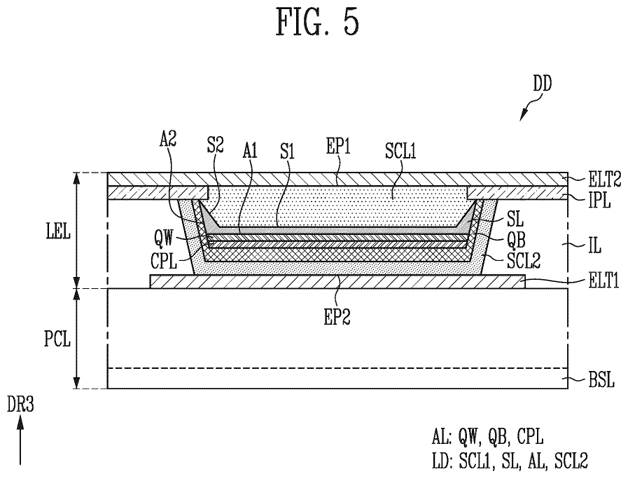

Referring to FIG. 1, the display device DD is configured to emit light. The display device DD includes a light emitting element LD (refer to FIG. 5). According to an embodiment, the display device DD may be a device that displays a moving image and/or a still image. The display device DD may be used as a display screen of various suitable products such as not only a portable electronic device such as, for example, a mobile phone, a smart phone, a tablet personal computer (PC), a smart watch, a watch phone, a mobile communication terminal, an electronic notebook, an electronic book, a portable multimedia player (PMP), a navigation device, and/or an ultra mobile PC (UMPC), but also a television, a notebook computer, a monitor, a billboard, and/or an Internet of things (IoT) device. However, an application field of the display device DD is not limited to a specific example.

The display device DD may be formed in a plane of a rectangular shape having a short side of a first direction DR1 and a long side of a second direction DR2 crossing the first direction DR1. A corner where the short side of the first direction DR1 and the long side of the second direction DR2 meet may be formed to be rounded to have a set or predetermined curvature or may be formed to have a right angle. A planar shape of the display device DD is not limited to a quadrangle, and may be formed to be in a shape of another polygon or may be formed to be in a round shape such as, for example, a circle or an ellipse. The display device may be formed to be flat, but is not limited thereto. For example, the display device DD may include a curved portion formed at left and right ends and having a constant curvature or a suitably varying curvature. In embodiments, the display device DD may be flexibly formed to be crooked, curved, bent, folded, and/or rolled.

In embodiments of the disclosure, the first direction DR1 may be a row direction of a pixel PXL and may be a “horizontal” direction. The second direction DR2 may be a column direction of the pixel PXL. A third direction DR3 may be a display direction of the display device DD or a normal direction of a plane in which a base layer BSL is provided.

The display device DD may include a display area DA and a non-display area NDA. The non-display area NDA may mean an area other than the display area DA. The non-display area NDA may surround at least a portion of the display area DA.

The base layer BSL may provide a base member of the display device DD. The base layer BSL may be a rigid or flexible substrate and/or film. For example, the base layer BSL may be a rigid substrate formed of glass and/or tempered glass, a flexible substrate (or a thin film) of a plastic and/or metal material, and/or at least one layer of an insulating layer (e.g., an electrically insulating layer). According to an embodiment, the base layer BSL may include silicon (Si). A material and/or a physical property of the base layer BSL are/is not particularly limited. According to an embodiment, the base layer BSL may be substantially transparent. Here, substantially transparent may mean that light (e.g., visible light) may be transmitted at one transmittance or more. In another embodiment, the base layer BSL may be translucent or opaque. In embodiments, the base layer BSL may include a reflective material.

The display area DA may be an area where the pixel PXL is provided. The non-display area NDA may be an area in which the pixel PXL is not provided. A driving circuit unit, lines, and pads connected to the pixel PXL of the display area DA may be in the non-display area NDA.

According to an embodiment, the pixels PXL (or the sub-pixels SPX) may be provided according to a stripe or a PENTILE® arrangement structure (e.g., an RGBG matrix, RGBG structure, or RGBG matrix structure) and/or the like. PENTILE® is a duly registered trademark of Samsung Display Co., Ltd. However, the disclosure is not necessarily limited thereto.

According to an embodiment, the pixel PXL (or sub-pixels SPX) may include a first sub-pixel SPX1, a second sub-pixel SPX2, and a third sub-pixel SPX3. At least one selected from the first sub-pixel SPX1, the second sub-pixel SPX2, and the third sub-pixel SPX3 may form one pixel unit PXU capable of emitting light of various suitable colors. In FIG. 1, an embodiment in which each pixel PXL includes three sub-pixels SPX1, SPX2, and SPX3, for example, the first sub-pixel SPX1, the second sub-pixel SPX2, and the third sub-pixel SPX3 is provided as an example, but embodiments of the present specification are not limited thereto.

According to an embodiment, the sub-pixels SPX may have a rectangular, square, or diamond planar shape. For example, each of the first sub-pixel SPX1, the second sub-pixel SPX2, and the third sub-pixel SPX3 may have a rectangular planar shape having a short side of a first direction DR1 and a long side of a second direction DR2 as shown in FIG. 1. Alternatively, the sub-pixels SPX may have a square or diamond planar shape including sides having the same length in the first direction DR1 and the second direction DR2.

In an example, areas of the first sub-pixel SPX1, the second sub-pixel SPX2, and the third sub-pixel SPX3 may be substantially same, but are not limited thereto. For example, at least one of the areas of the first sub-pixel SPX1, the second sub-pixel SPX2, and the third sub-pixel SPX3 may be different from another area. Alternatively, among the area of the first sub-pixel SPX1, the area of the second sub-pixel SPX2, and the area of the third sub-pixel SPX3, any two may be substantially same and the other may be different from the above-described two. Alternatively, the area of the first sub-pixel SPX1, the area of the second sub-pixel SPX2, and the area of the third sub-pixel SPX3 may be different from each other.

Referring to FIG. 2, the first sub-pixel SPX1 may be arranged with one of the second sub-pixel SPX2 and the third sub-pixel SPX3 in the first direction DR1 and may be arranged with the other one in the second direction DR2. For example, the first sub-pixel SPX1 may be arranged with the second sub-pixel SPX2 in the first direction DR1, and the first sub-pixel SPX1 may be arranged with the third sub-pixel SPX3 in the second direction DR2.

In an example, the third sub-pixel SPX3 may be adjacent to the first sub-pixel SPX1 and the second sub-pixel SPX2 along the second direction DR2. In an example, the areas of the first and second sub-pixels SPX1 and SPX2 may be substantially the same, and the area of the third sub-pixel SPX3 may be different from the areas of the first and second sub-pixels SPX1 and SPX2. For example, the area of the third sub-pixel SPX3 may be greater than the areas of the first and second sub-pixels SPX1 and SPX2.

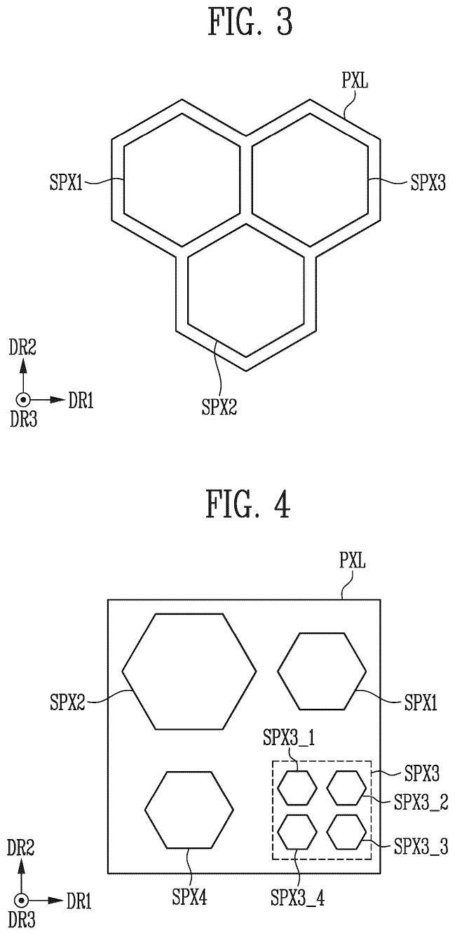

Referring to FIG. 3, each of the first sub-pixel SPX1, the second sub-pixel SPX2, and the third sub-pixel SPX3 may have a hexagonal (for example, regular hexagonal) planar shape. In an example, two adjacent surfaces of six surfaces of each of the first sub-pixel SPX1, the second sub-pixel SPX2, and the third sub-pixel SPX3 may face one surface of other adjacent sub-pixels SPX.

Referring to FIG. 4, the pixel PXL may further include a fourth sub-pixel SPX4. The fourth sub-pixel SPX4 may be arranged with the first sub-pixel SPX1 in a diagonal direction. For example, the first sub-pixel SPX1 may be disposed adjacent to the fourth sub-pixel SPX4 in a direction crossing between the first direction DR1 and the second direction DR2.

The first sub-pixel SPX1 may be arranged with the second sub-pixel SPX2 along the first direction DR1. The first sub-pixel SPX1 may be arranged with the third sub-pixel SPX3 along the second direction DR2.

The second sub-pixel SPX2 may be arranged with the fourth sub-pixel SPX4 along the second direction DR2. The second sub-pixel SPX2 may be arranged with the third sub-pixel SPX3 in a diagonal direction. For example, the second sub-pixel SPX2 may be disposed adjacent to the fourth sub-pixel SPX4 in a direction crossing between the second direction DR2 and a direction opposite to the first direction DR1.

The third sub-pixel SPX3 may be arranged with the fourth sub-pixel SPX4 along the first direction DR1.

According to an embodiment, the third sub-pixel SPX3 may include a plurality of sub-pixel portions spaced apart from each other. For example, the third sub-pixel SPX3 may include a (3_1)-th sub-pixel SPX3_1, a (3_2)-th sub-pixel SPX3_2, a (3_3)-th sub-pixel SPX3_3, and a (3_4)-th sub-pixel SPX3_4. The (3_1)-th sub-pixel SPX3_1, the (3_2)-th sub-pixel SPX3_2, the (3_3)-th sub-pixel SPX3_3, and the (3_4)-th sub-pixel SPX3_4 may be arranged along a clockwise direction.

For example, the (3_1)-th sub-pixel SPX3_1, the (3_2)-th sub-pixel SPX3_2, the (3_3)-th sub-pixel SPX3_3, and the (3_4)-th sub-pixel SPX3_4 may be sequentially disposed along four sides of a quadrangle. For example, the (3_1)-th sub-pixel SPX3_1 may be disposed at an upper left end of the quadrangle, the (3_2)-th sub-pixel SPX3_2 may be disposed at an upper right end of the quadrangle, the (3_3)-th sub-pixel SPX3_3 may be disposed at a lower right end of the quadrangle, and the (3_4)-th sub-pixel SPX3_4 may be disposed at a lower left end of the quadrangle.

According to an embodiment, the first sub-pixel SPX1, the second sub-pixel SPX2, and the third sub-pixel SPX3 (each of the (3_1)-th sub-pixel SPX3_1, the (3_2)-th sub-pixel SPX3_2, the (3_3)-th sub-pixel SPX3_3, and the (3_4)-th sub-pixel SPX3_4) may have different diameters (for example, a length of the longest diagonal among diagonals of the sub-pixel of FIG. 4). For example, the diameter of the second sub-pixel SPX2 may be greater than that of the first sub-pixel SPX1. The diameter of the first sub-pixel SPX1 may be greater than that of the third sub-pixel SPX3 (each of the (3_1)-th sub-pixel SPX3_1, the (3_2)-th sub-pixel SPX3_2, the (3_3)-th sub-pixel SPX3_3, and the (3_4)-th sub-pixel SPX3_4). The first sub-pixel SPX1 may have same diameter as the fourth sub-pixel SPX4.

According to an embodiment, the first sub-pixel SPX1, the second sub-pixel SPX2, and the third sub-pixel SPX3 (each of the (3_1)-th sub-pixel SPX3_1, the (3_2)-th sub-pixel SPX3_2, the (3_3)-th sub-pixel SPX3_3, and the (3_4)-th sub-pixel SPX3_4) may have different areas. The first sub-pixel SPX1 may have same area as the fourth sub-pixel SPX4.

According to an embodiment, the area of the second sub-pixel SPX2 may be greater than the area of the first sub-pixel SPX1. According to an embodiment, the area of the first sub-pixel SPX1 may be greater than areas of each of the (3_1)-th sub-pixel SPX3_1, the (3_2)-th sub-pixel SPX3_2, the (3_3)-th sub-pixel SPX3_3, and the (3_4)-th sub-pixel SPX3_4. According to an embodiment, the area of the first sub-pixel SPX1 may be same as the area of the fourth sub-pixel SPX4. However, the disclosure is not limited thereto.

In the disclosure, the first to fourth sub-pixels SPX1 to SPX4 may form one pixel PXL. According to an embodiment, the first sub-pixel SPX1 and the fourth sub-pixel SPX4 may emit first light, the second sub-pixel SPX2 may emit second light, and the third sub-pixel SPX3 may emit third light. Here, the first light may be light of a red wavelength band, the second light may be light of a green wavelength band, and the third light may be light of a blue wavelength band. The red wavelength band may be a wavelength band of about 600 nm to 750 nm, the green wavelength band may be a wavelength band of about 480 nm to 560 nm, and the blue wavelength band may be a wavelength band of about 370 nm to 460 nm, but embodiments of the present specification are not limited thereto.

Each of the first sub-pixel SPX1, the second sub-pixel SPX2, the third sub-pixel SPX3, and the fourth sub-pixel SPX4 may include an inorganic light emitting element including an inorganic material that emits light. For example, the light emitting element LD may be an inorganic light emitting element including an inorganic semiconductor and may be a micro light emitting diode (LED).

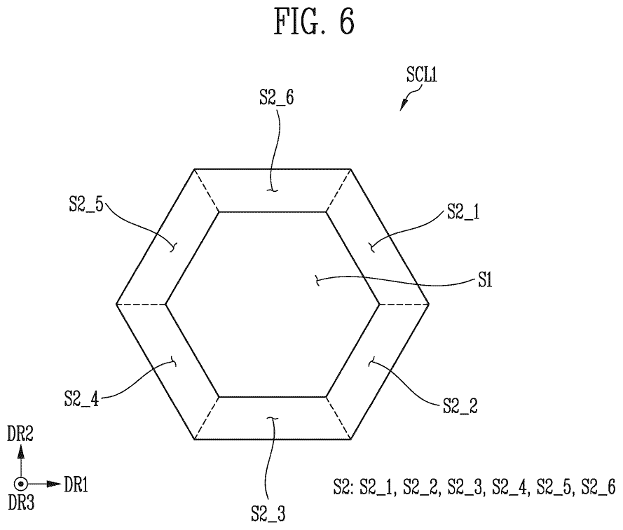

Hereinafter, the display device DD according to an embodiment is described with reference to FIGS. 5-6.

FIG. 5 is a schematic cross-sectional view of a display device according to an embodiment. FIG. 5 illustrates an embodiment in which an active layer AL includes a single-quantum well structure. FIG. 6 is a schematic plan view of a first semiconductor layer. FIG. 6 is a schematic diagram illustrating crystal surfaces of the first semiconductor layer SCL1.

Referring to FIG. 5, the display device DD may include a pixel circuit layer PCL and a light emitting element layer LEL.

The pixel circuit layer PCL may be a layer including a pixel circuit that drives the light emitting elements LD. The pixel circuit layer PCL may include a base layer BSL, conductive layers (e.g., electrically conductive layers) that form pixel circuits, and insulating layers (e.g., electrically insulating layers) between the conductive layers.

According to an embodiment, the pixel circuit may include circuit elements (for example, a driving transistor and/or the like), and may be electrically connected to the light emitting elements LD to provide an electrical signal for the light emitting elements LD to emit light.

The light emitting element layer LEL may be on the pixel circuit layer PCL. The light emitting element layer LEL may include the light emitting element LD, an insulating layer IPL (e.g., an electrically insulating layer IPL), a first electrode ELT1, a second electrode ELT2, and an intermediate layer IL.

The light emitting element LD may be on the pixel circuit layer PCL (or the base layer BSL). According to an embodiment, the light emitting element LD may include a first semiconductor layer SCL1, an auxiliary layer SL, the active layer AL, and a second semiconductor layer SCL2.

The light emitting element LD may have a first end EP1 and a second end EP2. According to an embodiment, the first semiconductor layer SCL1 may be adjacent to the first end EP1 of the light emitting element LD, and the second semiconductor layer SCL2 may be adjacent to the second end EP2.

The first semiconductor layer SCL1 may be on one surface of the active layer AL (or the auxiliary layer SL), and may include an n-type semiconductor according to an embodiment. For example, the first semiconductor layer SCL1 may include one or more selected from n-type doped AlGaInN, GaN, AlGaN, InGaN, AlN, and InN. The first semiconductor layer SCL1 may be doped with an n-type dopant. For example, the first semiconductor layer SCL1 may be n-GaN doped with the n-type dopant. However, the disclosure is not limited thereto, and the first semiconductor layer SCL1 may include various suitable n-type semiconductor materials generally available in the art.

The first semiconductor layer SCL1 may include a first surface S1 and a second surface S2 adjacent to the first surface S1.

The first surface S1 may be a generally flat surface. The first surface S1 may be generally parallel to the base layer BSL.

The first surface S1 may be a polar surface on which an n-type semiconductor is grown and may be a c-plane. According to an embodiment, the first surface S1 may be a {0001} crystal surface. In embodiments of the disclosure, the first surface S1 may be defined as a first crystal surface.

The second surface S2 may be an inclined surface with respect to the first surface S1 (e.g., may be inclined with respect to the first surface S1). The second surface S2 may be an inclined surface with respect to the base layer BSL (e.g., may be inclined with respect to the base layer BSL). For example, the second surface S2 may be an inclined sidewall (or side surface) of the first semiconductor layer SCL1. The second surface S2 may be inclined with respect to the first surface S1, and a width of the first semiconductor layer SCL1 may decrease as a distance from the base layer BSL decreases (or from the first end EP1 to the second end EP2). A cross-section of the first semiconductor layer SCL1 may have a trapezoidal shape.

The second surface S2 may be a semipolar surface on which an n-type semiconductor is grown. According to an embodiment, the second surface S2 may be a {n −n 0 k} crystal surface. Here, each of n and k is an integer of 1 or more. For example, the second surface S2 may be a {1 −1 0 1} crystal surface. However, the disclosure is not limited thereto. According to an embodiment, the second surface S2 may be a {n 0 −n k} crystal surface or a {n n −2n k} crystal surface. Here, each of n and k is an integer of 1 or more. In embodiments of the disclosure, the second surface S2 may be defined as a second crystal surface.

The second surface S2 may be a surface formed by epi-growth of a semiconductor and may be a non-etched surface. For example, the second surface S2 may be a crystal surface formed by epi-growth of a semiconductor.

Referring to FIG. 6, the first surface S1 may have a hexagonal shape in a plan view. In a plan view, the first surface S1 may have a hexagonal shape, and the light emitting element LD may have a truncated-inverted-pyramid shape. In embodiments, the light emitting element LD may have a truncated-pyramid shape. For example, the light emitting element LD may have a truncated hexagonal pillar shape. In FIG. 6, the first surface S1 is shown as having a hexagonal shape, but the disclosure is not limited thereto. The first surface S1 may have a circular, elliptical, or polygonal shape.

When the first surface S1 has a hexagonal shape, the second surface S2 may include a (2_1)-th surface S2_1, a (2_2)-th surface S2_2, a (2_3)-th surface S2_3, a (2_4)-th surface S2_4, a (2_5)-th surface S2_5, and a (2_6)-th surface S2_6. Each of the (2_1)-th surface S2_1, the (2_2)-th surface S2_2, the (2_3)-th surface S2_3, the (2_4)-th surface S2_4, the (2_5)-th surface S2_5, and the (2_6)-th surface S2_6 may be provided sequentially in a clockwise direction along the six sides of the first surface S1.

Each of the (2_1)-th surface S2_1, the (2_2)-th surface S2_2, the (2_3)-th surface S2_3, the (2_4)-th surface S2_4, the (2_5)-th surface S2_5, and the (2_6)-th surface S2_6 may be inclined with respect to the first surface S1. According to an embodiment, angles formed by the first surface S1 and each of the (2_1)-th surface S2_1, the (2_2)-th surface S2_2, the (2_3)-th surface S2_3, the (2_4)-th surface S2_4, the (2_5)-th surface S2_5, and the (2_6)-th surface S2_6 may be equal to each other. However, the disclosure is not limited thereto, and the angles formed by the first surface S1 and each of the (2_1)-th surface S2_1, the (2_2)-th surface S2_2, the (2_3)-th surface S2_3, the (2_4)-th surface S2_4, the (2_5)-th surface S2_5, and the (2_6)-th surface S2_6 may be different from each other.

The auxiliary layer SL may be on the first surface S1 and the second surface S2. The auxiliary layer SL may be adjacent to the first surface S1 and the second surface S2. According to an embodiment, the auxiliary layer SL may be directly on the first surface S1 and the second surface S2. According to an embodiment, the auxiliary layer SL may contact (e.g., physically contact) the first surface S1 and the second surface S2. According to an embodiment, the auxiliary layer SL may entirely cover the first surface S1 and the second surface S2.

The auxiliary layer SL may be between the first semiconductor layer SCL1 and the active layer AL, and may alleviate a stress difference between the first semiconductor layer SCL1 and the active layer AL. The auxiliary layer SL may have a superlattice structure.

For example, the auxiliary layer SL may include InGaN and GaN. According to an embodiment, the auxiliary layer SL may be formed in a structure in which InGaN and GaN are alternately stacked. However, the disclosure is not limited thereto.

The auxiliary layer SL may include a first auxiliary layer surface A1 and a second auxiliary layer surface A2.

The first auxiliary layer surface A1 may be a polar surface and may be a c-plane. The first auxiliary layer surface A1 may be adjacent to the first semiconductor layer SCL1. The first auxiliary layer surface A1 may be adjacent to the first surface S1. The first auxiliary layer surface A1 may be a generally flat surface. The first auxiliary layer surface A1 may be generally parallel to the base layer BSL.

The second auxiliary layer surface A2 may be a surface adjacent to the first auxiliary layer surface A1 and may be inclined with respect to the first auxiliary layer surface A1. The second auxiliary layer surface A2 may be an inclined surface with respect to the base layer BSL (e.g., may be inclined with respect to the base layer BSL). For example, the second auxiliary layer surface A2 may be an inclined sidewall (or side surface) of the auxiliary layer SL. The second auxiliary layer surface A2 may be a semipolar surface.

The active layer AL may be between the first semiconductor layer SCL1 and the second semiconductor layer SCL2. The active layer AL may include a single-quantum well or a multi-quantum well structure. For example, the active layer AL may have a single-quantum well structure including one well layer QW and one barrier layer QB as shown in FIG. 5.

The active layer AL may include the well layer QW and the barrier layer QB that form a quantum well structure. According to an embodiment, the active layer AL may further include a cap layer CPL.

The well layer QW may be between the first surface S1 (or the first auxiliary layer surface A1) and the second semiconductor layer SCL2. The well layer QW may be on the first surface S1 (or the first auxiliary layer surface A1). According to an embodiment, the well layer QW may be directly on the first auxiliary layer surface A1. According to an embodiment, the well layer QW may contact (e.g., physically contact) the first auxiliary layer surface A1. According to an embodiment, the well layer QW may entirely cover the first auxiliary layer surface A1. The well layer QW may contact (e.g., physically contact) the crystal surface of the c-plane.

The well layer QW may not be between the second surface S2 and the second semiconductor layer SCL2 when viewed in the first direction DR1 or the second direction DR2. The well layer QW may not contact (e.g., may not physically contact) the second surface S2 (or the second auxiliary layer surface A2). The well layer QW may not cover the second auxiliary layer surface A2. The well layer QW may not contact (e.g., may not physically contact) the semipolar crystal surface.

The well layer QW may not contact a side surface (for example, the second auxiliary layer surface A2) of the auxiliary layer SL and may expose the side surface of the auxiliary layer SL. The well layer QW according to embodiments of the disclosure may not be on the second auxiliary layer surface A2, and thus color purity of the light emitting element LD may be increased.

According to an embodiment, the well layer QW may include In. According to an embodiment, the well layer QW may include InGaN. However, the disclosure is not limited thereto, and the well layer QW may include a well layer of any suitable material generally used in the art.

According to an embodiment, the cap layer CPL may be on the well layer QW. According to an embodiment, at least a portion of the cap layer CPL may be between the well layer QW and the barrier layer QB. According to an embodiment, the cap layer CPL may be directly on the well layer QW. According to an embodiment, the cap layer CPL may contact (e.g., physically contact) the well layer QW. The cap layer CPL may cover one surface of the well layer QW. According to an embodiment, the cap layer CPL may not contact (e.g., may not physically contact) the side surface (for example, the second auxiliary layer surface A2) of the auxiliary layer SL and may expose the side surface of the auxiliary layer SL. However, a position of the cap layer CPL is not limited in embodiments of the disclosure.

For example, in FIG. 5, the active layer AL has a structure in which the cap layer CPL is between the well layer QW and the barrier layer QB (for example, a structure in which the well layer QW, the cap layer CPL, and the barrier layer QB are sequentially stacked), but the structure of the active layer AL is not limited thereto. According to an embodiment, the active layer AL may have a structure in which the cap layer CPL is at the uppermost portion. For example, the active layer AL may have a structure in which the barrier layer QB, the well layer QW, and the cap layer CPL are sequentially stacked on the auxiliary layer SL. For example, the barrier layer QB may entirely contact (e.g., entirely physically contact) the auxiliary layer SL, the well layer QW may be on the barrier layer QB, and the cap layer CPL may be on the well layer QW. According to an embodiment, the active layer AL may have a structure in which the well layer QW, the barrier layer QB, and the cap layer CPL are sequentially stacked on the auxiliary layer SL. For example, at least a portion of the barrier layer QB may be between the well layer QW and the cap layer CPL, and the cap layer CPL may be on at least a portion of the barrier layer QB.

The cap layer CPL may include a group III nitride semiconductor. For example, the cap layer CPL may include one or more selected from GaN, AlN, and AlₓGa_{y}N_{z} (0≤x≤1, 0≤y≤1, 0≤z≤1, 0≤x+y+z≤1). According to an embodiment, when the cap layer CPL includes AlₓGa_{y}N_{z}, in a chemical formula of AlₓGa_{y}N_{z} (0≤x≤1, 0≤y≤1, 0≤z≤1, 0x+y+z≤1), Al may have a composition of 25 mol % or more and less than 100 mol % with respect to Ga.

The cap layer CPL may have a thickness of 0.5 nm to 2.5 nm. However, the disclosure is not limited thereto. Hereinafter, in embodiments of the disclosure, a thickness of one component may be defined as a direction perpendicular to a plane in which one component is provided.

The cap layer CPL may have the same diameter as the barrier layer QW in a plan view according to an embodiment. The cap layer CPL may have the same area as the barrier layer QW in a plan view according to an embodiment.

The barrier layer QB may be between the auxiliary layer SL and the second semiconductor layer SCL2. The barrier layer QB may be between the first surface S1 (or the first auxiliary layer surface A1) and the second semiconductor layer SCL2. The barrier layer QB may be on the first surface S1 (or the first auxiliary layer surface A1). According to an embodiment, at least a portion of the barrier layer QB may be on the cap layer CPL. The barrier layer QB may be between the second surface S2 (or the second auxiliary layer surface A2) and the second semiconductor layer SCL2 when viewed in the first direction DR1 or the second direction DR2. At least a portion of the barrier layer QB may be on at least a portion of the auxiliary layer SL.

According to an embodiment, the barrier layer QB may include GaN. However, the disclosure is not limited thereto, and the barrier layer QB may include a barrier layer of any suitable material generally used in the art.

The second semiconductor layer SCL2 may be on another surface of the active layer AL, and may include a p-type semiconductor according to an embodiment. For example, the second semiconductor layer SCL2 may include one or more selected from p-type doped AlGaInN, GaN, AlGaN, InGaN, AlN, and InN. The second semiconductor layer SCL2 may be doped with a p-type dopant. For example, the second semiconductor layer SCL2 may be p-GaN doped with the p-type dopant. However, the disclosure is not limited thereto, and the second semiconductor layer SCL2 may include various suitable p-type semiconductor materials generally used in the art.

According to an embodiment, at least a portion of the second semiconductor layer SCL2 may be on the cap layer CPL. According to an embodiment, the second semiconductor layer SCL2 may be on the barrier layer QB. According to an embodiment, the second semiconductor layer SCL2 may contact (e.g., physically contact) the barrier layer QB. According to an embodiment, the second semiconductor layer SCL2 may entirely cover the barrier layer QB. However, the disclosure is not limited thereto, and an electron blocking layer may be further between the barrier layer QB and the second semiconductor layer SCL2.

The intermediate layer IL may be on the pixel circuit layer PCL. The intermediate layer IL may be between the light emitting elements LD. According to an embodiment, the intermediate layer IL may be an insulating layer (e.g., an electrically insulating layer). The intermediate layer IL may fill at least a portion of a space between the light emitting elements LD.

According to an embodiment, the intermediate layer IL may include an organic material and/or an inorganic material. For example, the organic material may include one or more selected from a group of acryl resin, epoxy resin, phenol resin, polyamide resin, polyimide resin, polyester resin, polyphenylenesulfide resin, and benzocyclobutene. For example, the inorganic material may include one or more selected from a group of silicon nitride (SiNx), aluminum nitride (AINx), titanium nitride (TiNx), silicon oxide (SiOx), aluminum oxide (AlxOy), titanium oxide (TiOx), silicon oxycarbide (SiOxCy), and silicon oxynitride (SiOxNy). However, the disclosure is not limited thereto.

The insulating layer IPL may be on the intermediate layer IL. At least a portion of the insulating layer IPL may contact (e.g., physically contact) at least a portion of the first semiconductor layer SCL1. At least a portion of the insulating layer IPL may contact (e.g., physically contact) at least a portion of the second semiconductor layer SCL2.

The insulating layer IPL may include an insulating material (e.g., an electrically insulating material). For example, the insulating layer IPL may include silicon oxide (SiOx). For example, the insulating layer IPL may include silicon dioxide (SiO₂). The insulating layer IPL may include an insulating material (e.g., an electrically insulating material) and electrically insulate the second semiconductor layer SCL2 and the second electrode ELT2. For example, the insulating layer IPL may prevent or reduce contact (e.g., physical contact) between the second semiconductor layer SCL2 and the second electrode ELT2.

According to an embodiment, the first electrode ELT1 may be an anode electrode and the second electrode ELT2 may be a cathode electrode. The first electrode ELT1 may be electrically connected to the first semiconductor layer SCL2, and the second electrode ELT2 may be electrically connected to the second semiconductor layer SCL2.

According to an embodiment, the first electrode ELT1 and the second electrode ELT2 may include a conductive material (e.g., an electrically conductive material). For example, the first electrode ELT1 may include a conductive material (e.g., an electrically conductive material) having a reflective property, and the second electrode ELT2 may include a transparent conductive material, but the disclosure is not necessarily limited thereto.

According to an embodiment, the display device DD may further include an encapsulation layer. The encapsulation layer may be on the light emitting element LD (for example, the second electrode ELT2). The encapsulation layer may include a plurality of insulating layers (e.g., electrically insulating layers) covering the light emitting element LD. According to an embodiment, the encapsulation layer may have a structure in which an inorganic layer and an organic layer are alternately stacked.

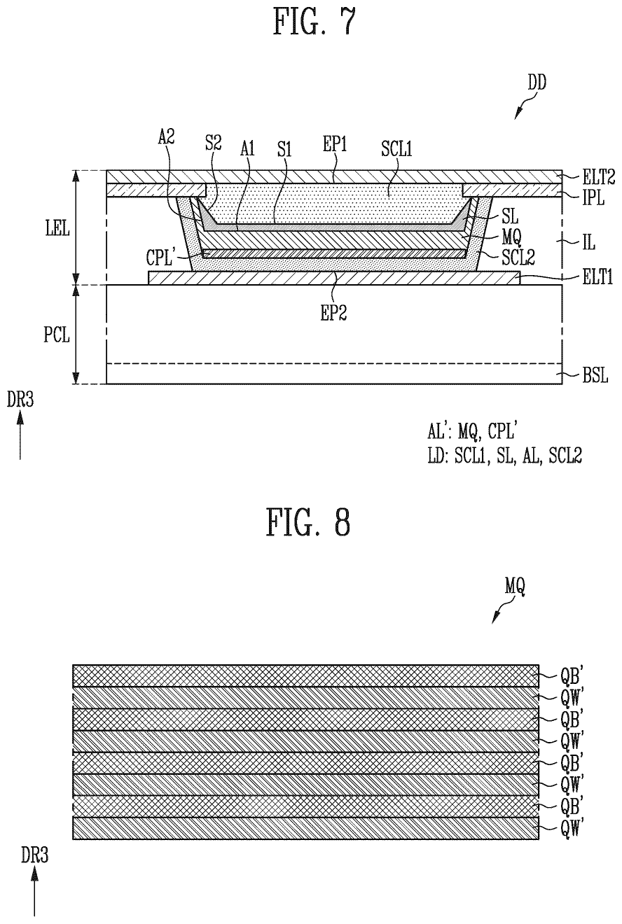

Hereinafter, a display device DD in which an active layer AL′ has a multi-well structure according to an embodiment is described with reference to FIGS. 7-8. The embodiment shown in FIGS. 7-8 is different from the embodiment shown in FIG. 5 in that the active layer AL′ has a multi-well structure. Hereinafter, a description of a content that overlaps the above-described content is not repeated.

FIG. 7 is a schematic cross-sectional view of a display device according to an embodiment. FIG. 7 may illustrate an embodiment in which the active layer AL′ includes a multi-quantum well structure. FIG. 8 is a schematic cross-sectional view of a multi-quantum well layer according to an embodiment. FIG. 8 is a schematic diagram according to an embodiment of the multi-quantum well layer MQ of FIG. 7.

Referring to FIGS. 7-8, the active layer AL′ may have the multi-quantum well structure including the multi-quantum well layer MQ. The multi-quantum well layer MQ may be on the auxiliary layer SL. The multi-quantum well layer MQ may be between the first semiconductor layer SCL1 and the second semiconductor layer SCL2.

The multi-quantum well layer MQ may include at least two well layers QW′ and at least two barrier layers QB′. The well layers QW′ and the barrier layers QB′ may be provided alternately with each other.

Even though the active layer AL′ includes the multi-quantum well layer MQ, the well layers QW′ may not contact (e.g., may not physically contact) the semipolar crystal surface as described above. For example, the well layer QW′ may expose a side surface of a surface under the well layer QW′.

According to an embodiment, the multi-quantum well layer MQ may have a structure in which the well layer QW′ is at the lowermost portion, the barrier layer QB′ is on the well layer QW′, and the well layers QW′ and the barrier layers QB′ are alternately provided. In embodiments, the barrier layer QB′ may be directly on the auxiliary layer SL. However, the disclosure is not limited thereto.

According to an embodiment, the multi-quantum well layer MQ may have a structure in which the barrier layer QB′ is at the lowermost portion, the well layer QW′ is on the barrier layer QB′, and the well layers QW and the barrier layers QB′ are alternately provided. In embodiments, the well layer QW′ may be directly on the auxiliary layer SL.

According to an embodiment, a cap layer CPL′ may be on the multi-quantum well layer MQ. According to an embodiment, the cap layer CPL′ may be at the uppermost portion of the active layer AL′. However, the disclosure is not limited thereto.

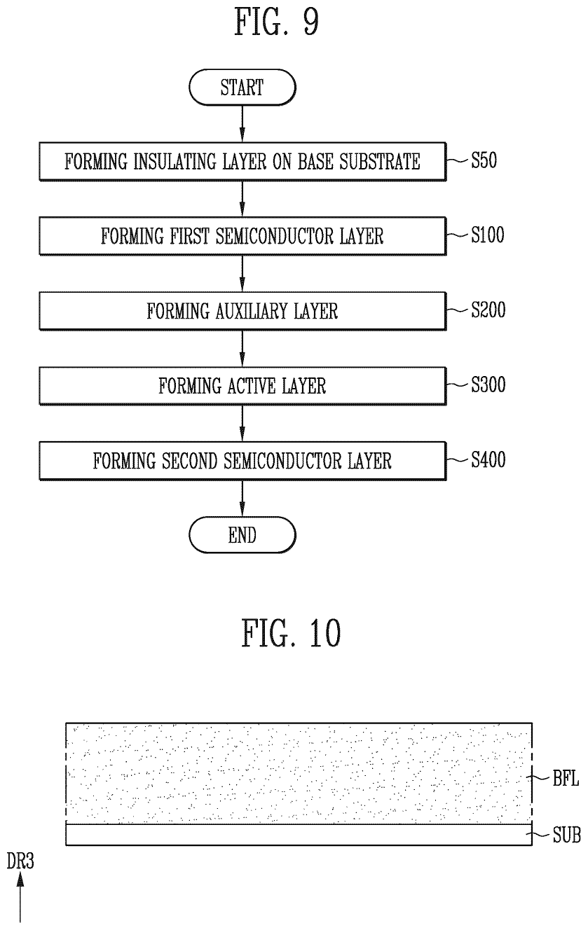

Hereinafter, a method of manufacturing the light emitting element LD according to embodiments of the disclosure is described with reference to FIGS. 9-18. FIG. 9 is a flowchart schematically illustrating a method of manufacturing a light emitting element. FIGS. 10-18 are schematic cross-sectional views illustrating a method of manufacturing a light emitting element.

Referring to FIG. 9, the method of manufacturing the light emitting element LD may include forming an insulating layer (e.g., an electrically insulating layer) on a base substrate (S50), forming a first semiconductor layer (S100), forming an auxiliary layer (S200), forming an active layer (S300), and forming a second semiconductor layer (S400).

Referring to FIG. 10, in forming the insulating layer on the base substrate (S50), the base substrate SUB may be prepared. The base substrate SUB may include a sapphire substrate and/or a transparent substrate such as glass. However, the disclosure is not limited thereto.

According to an embodiment, the base substrate SUB may include GaN, SiC, ZnO, Si, GaP, GaAs, and/or the like, and the base substrate SUB may include a conductive substrate (e.g., an electrically conductive substrate).

According to an embodiment, a buffer layer BFL may be selectively formed on the base substrate SUB. The buffer layer BFL may be on one surface (or an upper surface) of the base substrate SUB.

The buffer layer BFL may serve to reduce a lattice constant difference between the first semiconductor layer SCL1 formed on the buffer layer BFL and the base substrate SUB.

The buffer layer BFL may include an undoped semiconductor. The buffer layer BFL may include substantially the same material as the first semiconductor layer SCL1, and may be a material that is not doped with an n-type or a p-type dopant, or a doping concentration may be less than that of the first semiconductor layer SCL1. For example, the buffer layer BFL may include one or more selected from AlGaInN, GaN, AlGaN, InGaN, AlN, and InN. However, the disclosure is not limited thereto.

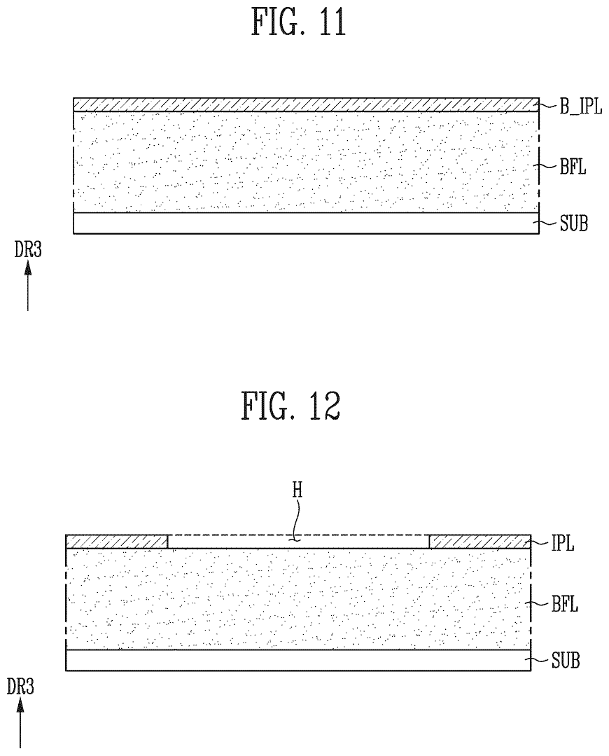

Referring to FIGS. 11-12, in forming the insulating layer on the base substrate (S50), the insulating layer IPL may be formed on the buffer layer BFL (or the base substrate SUB).

Forming the insulating layer on the base substrate (S50) may include forming a base insulating layer B_IPL on the base substrate SUB. To form the insulating layer IPL, the base insulating layer B_IPL may be formed (or provided) on the buffer layer BFL (or the base substrate SUB).

The base insulating layer B_IPL may be a base layer that forms the insulating layer IPL and may include an insulating material (e.g., an electrically insulating material). For example, the base insulating layer B_IPL may include silicon oxide (SiOx). For example, the base insulating layer B_IPL may include silicon dioxide (SiO₂).

The base insulating layer B_IPL may be deposited on the buffer layer BFL (or the base substrate SUB) by a plasma-enhanced chemical vapor deposition (PECVD) process. The base insulating layer B_IPL may be deposited to have a thickness of 100 nm to 500 nm.

Forming the insulating layer on the base substrate (S50) may include etching the base insulating layer B_IPL. The base insulating layer B_IPL may be etched through a photo lithography process, an E-beam lithography process, a nanoimprint lithography (NIL) process, and/or the like.

The base insulating layer B_IPL may be etched to define an opening H. For example, the base insulating layer B_IPL may be etched to expose at least a portion of the buffer layer BFL. The opening H may expose at least a portion of the buffer layer BFL.

According to an embodiment, the base insulating layer B_IPL may be etched to form a fine pattern having a plurality of micro-scale and/or nano-scale of openings H. According to an embodiment, the opening H may be 1 μm or less (e.g., may be 1 μm or less across in a direction perpendicular to the third direction DR3). However, the disclosure is not limited thereto, and a size of the opening H may change according to a wavelength of light emitted by the light emitting element LD. For example, a light emitting element LD that emits green light may be manufactured to have an opening H that is wider than a light emitting element LD that emits red light.

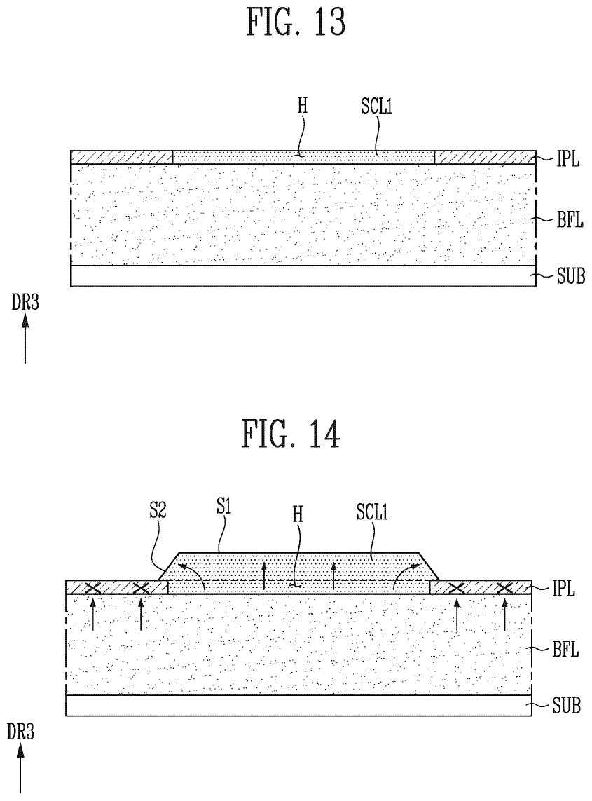

Referring to FIG. 13, in forming the first semiconductor layer (S100), the first semiconductor layer SCL1 may be formed on the buffer layer BFL. The first semiconductor layer SCL1 may be formed in the opening H.

Forming the first semiconductor layer (S100) may include growing the first semiconductor layer SCL1 on the buffer layer BFL. The first semiconductor layer SCL1 may be formed by growing a seed crystal by an epitaxial method.

According to an embodiment, the first semiconductor layer SCL1 may be formed by electron beam deposition, physical vapor deposition (PVD), chemical vapor deposition (CVD), plasma laser deposition (PLD), dual-type thermal evaporation, sputtering, and/or metal organic chemical vapor deposition (MOCVD). According to an embodiment, the first semiconductor layer SCL1 may be formed by the MOCVD, but the disclosure is not necessarily limited thereto.

Referring to FIG. 14, in forming the first semiconductor layer (S100), the seed crystal that forms the first semiconductor layer SCL1 may grow in a direction perpendicular to a plane in which the base substrate SUB is provided. The first semiconductor layer SCL1 may be formed by selective area growth. For example, a seed crystal that overlaps the opening H may grow in the direction perpendicular to the plane in which the base substrate SUB is provided, but a seed crystal that overlaps the insulating layer IPL may not grow in the direction perpendicular to the plane in which the base substrate SUB is provided. Accordingly, stress may be alleviated when the first semiconductor layer SCL1 is grown.

Forming the first semiconductor layer (S100) may include forming the first semiconductor layer SCL1 having the first surface S1 and the second surface S2. The first semiconductor layer SCL1 may be grown to form the first surface S1.

The first surface S1 may be a generally flat surface. The first surface S1 may be generally parallel to the base substrate SUB.

The first surface S1 may be a polar surface and may be a c-plane. According to an embodiment, the first surface S1 may be a {0001} crystal surface.

The first semiconductor layer SCL1 may be grown and may form the second surface S2 inclined with respect to the first surface S1. The second surface S2 may be an inclined surface with respect to the base substrate SUB (e.g., may be inclined with respect to the base substrate SUB). For example, the second surface S2 may be an inclined sidewall of the first semiconductor layer SCL1. The second surface S2 may be inclined with respect to the first surface S1, and a width of the first semiconductor layer SCL1 may increase as a distance from the base substrate SUB increases (or in the third direction DR3).

Experimentally, when the first semiconductor layer SCL1 is formed by a selective growth technique, while a seed crystal growth direction is bent, the second surface S2 may be formed.

Therefore, the second surface S2 may be a semipolar surface of which a crystal growth direction is different from that of the first surface S1. According to an embodiment, the second surface S2 may be a {n −n 0 k} crystal surface. Here, each of n and k is an integer of 1 or more. For example, the second surface S2 may be a {1 −1 0 1} crystal surface. However, the disclosure is not limited thereto. According to an embodiment, the second surface S2 may be a {n 0 −n k} crystal surface or a {n n −2n k} crystal surface. Here, each of n and k is an integer of 1 or more.

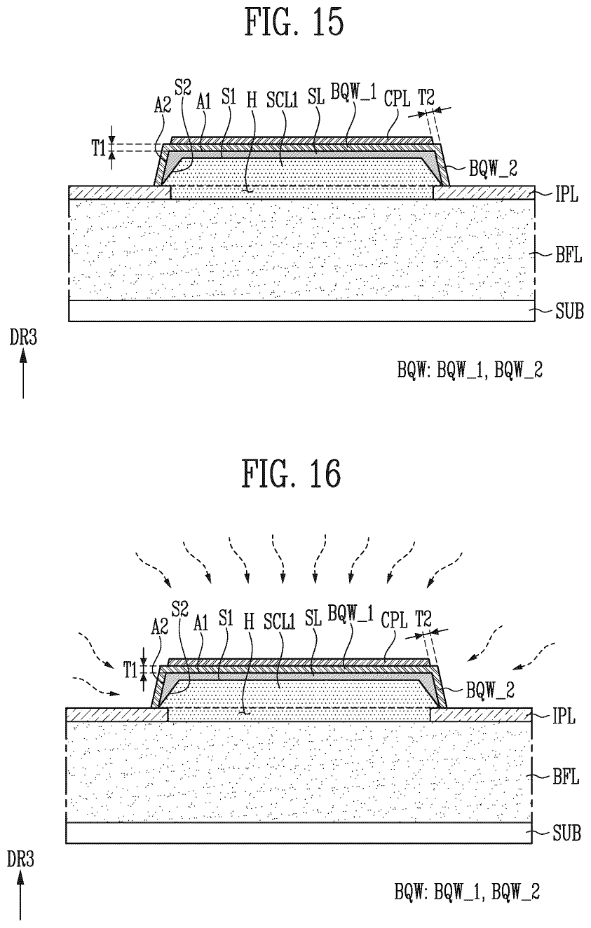

Referring to FIG. 15, forming the auxiliary layer (S200), the auxiliary layer SL may be formed on the first semiconductor layer SCL1. The auxiliary layer SL may be on the first surface S1 and the second surface S2. According to an embodiment, the auxiliary layer SL may be directly on the first surface S1 and the second surface S2. According to an embodiment, the auxiliary layer SL may contact (e.g., physically contact) the first surface S1 and the second surface S2. According to an embodiment, the auxiliary layer SL may entirely cover the first surface S1 and the second surface S2.

Forming the auxiliary layer (S200) may include forming the auxiliary layer SL having the first auxiliary layer surface A1 and the second auxiliary layer surface A2.

The first auxiliary layer surface A1 may be generally parallel to the first surface S1, and may be a polar surface and a c-plane. The first auxiliary layer surface A1 may be adjacent to the first surface S1. The second auxiliary layer surface A2 may be an inclined surface with respect to the first auxiliary layer surface A1 (e.g., may be inclined with respect to the first auxiliary layer surface A1). The second auxiliary layer surface A2 may be adjacent to the first auxiliary layer surface A1. The second auxiliary layer surface A2 may be a semipolar surface. The second auxiliary layer surface A2 may be a sidewall of the auxiliary layer SL.

The auxiliary layer SL may include InGaN and GaN. According to an embodiment, the auxiliary layer SL may be formed in a structure in which InGaN and GaN are alternately stacked. However, the disclosure is not limited thereto.

Forming the active layer (S300) may include forming the well layer QW and forming the cap layer CPL.

Forming the active layer (S300), in order to form the well layer QW, a base well layer B_QW may be formed on the auxiliary layer SL, and the cap layer CPL may be formed on the base well layer B_QW.

The base well layer B_QW may include a first portion BQW_1 and a second portion BQW_2. The first portion BQW_1 and the second portion BQW_2 may be a layer deposited and formed in the same process and may include the same material. For example, the first portion BQW_1 and the second portion BQW_2 may include In. For example, the first portion BQW_1 and the second portion BQW_2 may include InGaN. However, the disclosure is not limited thereto.

The first portion BQW_1 may be a portion formed on the first auxiliary layer surface A1 (or an upper surface of the auxiliary layer SL) and may have a first thickness T1. The second portion BQW_2 may be a portion formed on the second auxiliary layer surface A2 (or a side surface of the auxiliary layer SL) and may have a second thickness T2. The first thickness T1 may be thicker than the second thickness T2. For example, the first thickness T1 and the second thickness T2 may have a ratio of 3:1. However, the disclosure is not limited thereto.

Experimentally, because In has a long surface diffusion distance, when the base well layer B_QW includes In, more of the base well layer B_QW may be deposited on the c-plane than on the semipolar surface. Accordingly, the first thickness T1 may be thicker than the second thickness T2, and light of different colors may be emitted from the first portion BQW_1 and the second portion BQW_2. For example, the first portion BQW_1 may emit light of a wavelength longer than a wavelength of light emitted from the second portion BQW_2. For example, the first portion BQW_1 may emit red light, and the second portion BQW_2 may emit green or blue light. For example, the first portion BQW_1 may emit green light, and the second portion BQW_2 may emit blue light.

When light of different colors are emitted from the first portion BQW_1 and the second portion BQW_2, and when a density of a current applied to the light emitting element LD increases when driving the light emitting element LD, two or more types (or kinds) of light may be emitted, and thus a risk that color purity of the light emitting element LD may be deteriorated may exist.

In the light emitting element LD according to embodiments of the disclosure, the second portion BQW_2 may be removed, the second portion BQW_2 may not be on a side surface (or the second auxiliary layer surface A2) of the auxiliary layer SL (or a side surface of the first semiconductor layer SCL1), and color purity of the light emitting element LD may be increased.

The cap layer CPL may be on the first portion BQW_1. The cap layer CPL may be directly on the first portion BQW_1. According to an embodiment, the cap layer CPL may contact (e.g., physically contact) the first portion BQW_1. The cap layer CPL may cover one surface of the first portion BQW_1. According to an embodiment, the cap layer CPL may not contact (e.g., may not physically contact) the side surface (for example, the second auxiliary layer surface A2) of the auxiliary layer SL, and may expose the side surface of the auxiliary layer SL.

The cap layer CPL may include a group III nitride semiconductor. For example, the cap layer CPL may include one or more selected from GaN, AlN, and AlₓGa_{y}N_{z} (0≤x≤1, 0≤y≤1, 0≤z≤1, 0≤x+y+z≤1).

Referring to FIG. 16, forming the active layer (S300) (or forming the well layer QW) may include removing the second portion BQW_2. According to an embodiment, after forming the cap layer CPL, the second portion BQW_2 may be removed.

The second portion BQW_2 may be etched by an etching process. The second portion BQW_2 may be etched by dry etching, wet etching, laser etching, and/or the like.

The second portion BQW_2 may have a thickness thinner than that of the first portion BQW_1, and thus even though the second portion BQW_2 is completely etched, the first portion BQW_1 may be on at least a portion of the auxiliary layer SL.

When the second portion BQW_2 is removed by dry etching, the second portion BQW_2 may be removed by an in-situ process. For example, the second portion BQW_2 may be etched in a chamber equal to a chamber in which the second portion BQW_2 is formed. When the second portion BQW_2 is removed through an in-situ process, movement between chambers may be reduced, and thus a process may become convenient.

When the second portion BQW_2 is removed by dry etching, an etching gas may be provided in the chamber. When the second portion BQW_2 is removed by dry etching, removing the second portion BQW_2 may include flowing the etching gas in the chamber.

The etching gas may include nitrogen (N₂) gas and hydrogen (H₂) gas. In a step in which the etching gas flows in the chamber, with respect to a flow rate of the entire etching gas, the hydrogen (H₂) gas may flow at a flow rate of 5% or more and less than 25% compared to the total gas flow of the nitrogen (N₂) gas and the hydrogen (H₂) gas. For example, when the nitrogen (N₂) gas and the hydrogen (H₂) gas flow at a total of 100 L per hour, the hydrogen (H₂) gas may flow at 5 L or more and less than 25 L per hour.

The hydrogen (H₂) gas may remove indium (In). Because the binding energy of indium (In) is relatively low, the indium (In) may be removed by an etching gas before other materials.

When the hydrogen (H₂) gas flows at a flow rate of less than 5% compared to the total gas flow rate of the nitrogen (N₂) gas and the hydrogen (H₂) gas, the etching gas may not properly etch the second portion BQW_2. For example, the etching gas may not completely etch the second portion BQW_2, and thus the second portion BQW_2 may remain on the side surface of the auxiliary layer SL.

When the hydrogen (H₂) gas flows at a gas flow rate of 25% or more compared to the total gas flow rate of the nitrogen (N₂) gas and the hydrogen (H₂) gas, the etching gas may completely etch the first portion BQW_1. When the etching gas completely etches the first portion BQW_1, the well layer QW may not be formed, and thus the light emitting element LD may not be properly formed.

When the second portion BQW_2 is removed by wet etching, the second portion BQW_2 may be removed by an ex-situ process. For example, in a chamber different from the chamber in which the second portion BQW_2 is formed, the second portion BQW_2 may be immersed in an etchant, and the second portion BQW_2 may be etched.

When the second portion BQW_2 is removed by laser etching, the second portion BQW_2 may be removed by an ex-situ process. For example, in a chamber different from the chamber in which the second portion BQW_2 is formed, a laser may be irradiated to the second portion BQW_2, and the second portion BQW_2 may be etched.

In the light emitting element LD according to the disclosure, the second portion BQW_2 may be removed, and thus light may be emitted from the first portion BQW_1, thereby improving color purity of the light emitting element LD.

In forming the active layer (S300), after the second portion BQW_2 is removed, a recovery process may be performed. For example, a heat treatment process may be performed. For example, one surface (or one surface of the first portion BQW_1) of the cap layer CPL may be heat treated.

When the second portion BQW_2 is etched, a surface of the cap layer CPL (or the first portion BQW_1) may become uneven. The method of manufacturing the light emitting element LD according to an embodiment of the disclosure may reduce the surface unevenness of the cap layer CPL (or the first portion BQW_1) through a heat treatment process, and thus crystallinity of the first portion BQW_1 may be properly secured.

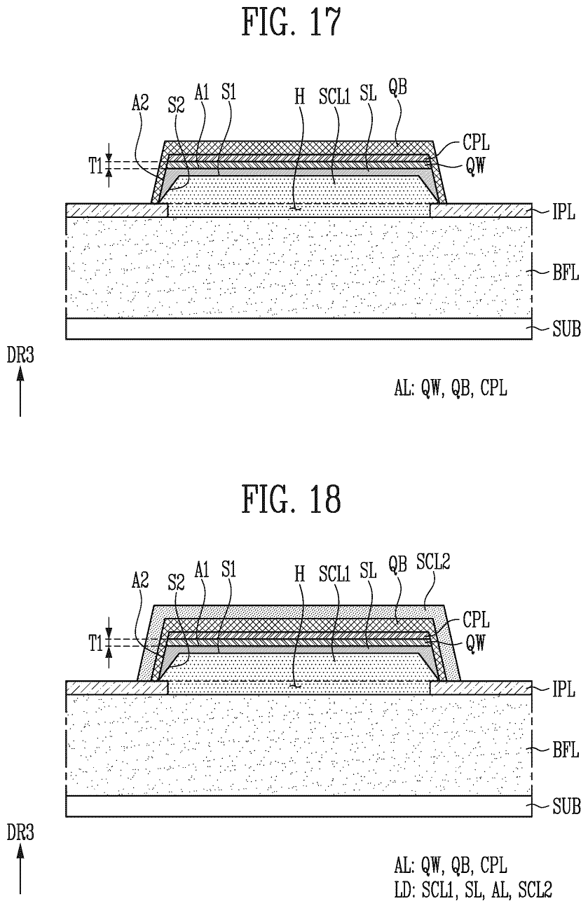

Referring to FIG. 17, forming the active layer (S300) may include forming the barrier layer QB. In forming the active layer (S300), the barrier layer QB may be formed on the auxiliary layer SL. At least a portion of the barrier layer QB may cover the cap layer CPL, and a remaining portion of the barrier layer QB may cover the side surface (for example, the second auxiliary layer surface A2) of the auxiliary layer SL.

The barrier layer QB may include GaN. However, the disclosure is not limited thereto, and the barrier layer QB may include a barrier layer of any suitable material generally used in the art.

Referring to FIG. 7, when the active layer AL has the multi-well structure (e.g., the multi-quantum well layer MQ), forming the well layer QW′ and forming the barrier layer QB′ may be performed at least twice. For example, the above-described processes may be performed so that the well layers QW′ and the barrier layers QB′ are alternately provided.

Referring to FIG. 16, in forming the second semiconductor layer (S400), the second semiconductor layer SCL2 may be formed on the active layer AL. According to an embodiment, the second semiconductor layer SCL2 may be directly on the active layer AL. However, the disclosure is not limited thereto, and according to an embodiment, the electron blocking layer EBL may be further formed between the active layer AL and the second semiconductor layer SCL2.

According to an embodiment, at least a portion of the second semiconductor layer SCL2 may be on the cap layer CPL. According to an embodiment, the second semiconductor layer SCL2 may be on the barrier layer QB.

The second semiconductor layer SCL2 may be on another surface of the active layer AL, and may include a p-type semiconductor according to an embodiment. For example, the second semiconductor layer SCL2 may include one or more selected from p-type doped AlGaInN, GaN, AlGaN, InGaN, AlN, and InN. The second semiconductor layer SCL2 may be doped with a p-type dopant. For example, the second semiconductor layer SCL2 may be p-GaN doped with the p-type dopant. However, the disclosure is not limited thereto, and the second semiconductor layer SCL2 may include various suitable p-type semiconductor materials generally used in the art.

After the second semiconductor layer SCL2 is formed, the light emitting element LD may be transferred onto the pixel circuit layer PCL. A method in which the light emitting element LD is transferred onto the pixel circuit layer PCL is not particularly limited. For example, the light emitting element LD may be picked up by a separate carrier substrate and may be transferred onto the pixel circuit layer PCL. In embodiments, for example, the light emitting element LD may be separated from the base substrate SUB by a mechanical lift-off process.

According to an embodiment, when the light emitting element LD is separated from the base substrate SUB and transferred onto the pixel circuit layer PCL, the insulating layer IPL may remain as is, and the insulating layer IPL may be transferred onto the pixel circuit layer PCL together with the light emitting element LD.

As described above, although the disclosure has been described with reference to example embodiments above, those skilled in the art or those having ordinary skill in the art will understand that the subject matter of this disclosure may be variously modified and changed without departing from the spirit and technical area of the disclosure described in the appended claims.

Therefore, the technical scope of the disclosure should not be limited to the contents described in the detailed description of the specification, but should be defined by the appended claims, and equivalents thereof.

What is claimed is:

1. A light emitting element comprising:
a first semiconductor layer;
an auxiliary layer on the first semiconductor layer;
an active layer on the auxiliary layer; and
a second semiconductor layer on the active layer,
wherein the auxiliary layer comprises a first auxiliary layer surface adjacent to the first semiconductor layer and a second auxiliary layer surface which is a side surface adjacent to the first auxiliary layer surface,
the active layer comprises a well layer and a barrier layer,
the auxiliary layer has a superlattice structure, and
the well layer is on the first auxiliary layer surface without being on the second auxiliary layer surface of the auxiliary layer.

2. The light emitting element according to claim 1, wherein the second auxiliary layer surface is an inclined surface.

3. The light emitting element according to claim 1, wherein the first auxiliary layer surface and the well layer contact each other, and
the second auxiliary layer surface and the well layer do not contact each other.

4. The light emitting element according to claim 1, wherein the auxiliary layer has a structure in which InGaN and GaN are alternately stacked.

5. The light emitting element according to claim 1, wherein the first semiconductor layer comprises a first surface and a second surface which is a side surface adjacent to the first surface,
the first surface is a c-plane, and
the second surface is a semipolar surface.

6. The light emitting element according to claim 5, wherein the auxiliary layer entirely covers the first surface and the second surface.

7. The light emitting element according to claim 1, wherein the active layer further comprises a cap layer on the well layer, and the cap layer comprises one or more selected from AlN and AlₓGa_{y}N_{z} (0≤x≤1, 0≤y≤1, 0≤z≤1, 0≤x+y+z≤1).

8. The light emitting element according to claim 7, wherein in the AlₓGa_{y}N_{z} (0≤x≤1, 0≤y≤1, 0≤z≤1, 0≤x+y+z≤1), Al has a composition of 25 mol % or more and less than 100 mol % with respect to Ga.

9. The light emitting element according to claim 7, wherein the cap layer has a thickness of 0.5 nm to 2.5 nm.

10. The light emitting element according to claim 7, wherein the cap layer has a same diameter as the well layer.

11. The light emitting element according to claim 1, wherein the light emitting element has a truncated pyramid shape.

12. A method of manufacturing a light emitting element, the method comprising:
forming an insulating layer on a base substrate;
forming a first semiconductor layer on the base substrate;
forming an auxiliary layer on the first semiconductor layer;
forming an active layer on the auxiliary layer; and
forming a second semiconductor layer on the active layer,
wherein the forming the auxiliary layer on the first semiconductor layer comprises forming the auxiliary layer having a first auxiliary layer surface adjacent to the first semiconductor layer and a second auxiliary layer surface which is a side surface adjacent to the first auxiliary layer surface,
the forming the active layer on the auxiliary layer comprises forming the active layer including a well layer and a barrier layer,
the auxiliary layer has a superlattice structure, and
the well layer is on the first auxiliary layer surface without being disposed on the second auxiliary layer surface of the auxiliary layer.

13. The method according to claim 12, wherein the forming the first semiconductor layer on the base substrate comprises forming the first semiconductor layer having a first surface and a second surface adjacent to the first surface,
the first surface is a c-plane,
the second surface is a semipolar surface, and
the second auxiliary layer surface is an inclined surface with respect to the first auxiliary layer surface.

14. The method according to claim 12, wherein forming the well layer comprises:
forming a base well layer comprising a first portion and a second portion on the auxiliary layer; and
etching the second portion,
the first portion contacts the first auxiliary layer surface,
the second portion contacts the second auxiliary layer surface,
the second auxiliary layer surface is an inclined surface with respect to the first auxiliary layer surface, and
the second portion is etched and the well layer does not contact the second auxiliary layer surface.

15. The method according to claim 14, wherein the second portion is etched by an etching gas including nitrogen (N₂) gas and hydrogen (H₂) gas,
the hydrogen gas flows at a flow rate of 5% or more and less than 25% with respect to a flow rate of the nitrogen gas and the hydrogen gas, and
the second portion is removed by an in-situ process.

16. A display device comprising:
a base layer; and
a light emitting element on the base layer,
wherein the light emitting element comprises:
a first semiconductor layer;
an auxiliary layer on the first semiconductor layer;
an active layer on the auxiliary layer; and
a second semiconductor layer on the active layer,
the auxiliary layer comprises a first auxiliary layer surface adjacent to the first semiconductor layer and a second auxiliary layer surface which is a side surface adjacent to the first auxiliary layer surface,
the active layer comprises a well layer and a barrier layer,
the auxiliary layer has a superlattice structure, and
the well layer is on the first auxiliary layer surface without being on the second auxiliary layer surface of the auxiliary layer.

17. The display device according to claim 16, wherein the first semiconductor layer comprises a first surface and a second surface adjacent to the first surface,
the first side is a c-plane,
a second surface is a semipolar surface and a non-etched surface,
the second auxiliary layer surface is an inclined surface, and
the auxiliary layer entirely covers the first surface and the second surface.

18. The display device according to claim 16, wherein the active layer of the light emitting element further comprises a cap layer on the well layer, and
the cap layer comprises one or more selected from AlN and AlₓGa_{y}N_{z} (0≤x≤1, 0≤y≤1, 0≤z≤1, 0≤x+y+z≤1).

19. The display device according to claim 16, wherein the display device comprises a pixel,
the pixel comprises a first sub-pixel, a second sub-pixel, and a third sub-pixel, and
the first sub-pixel, the second sub-pixel, and the third sub-pixel each have different diameters, respectively.

20. The display device according to claim 19, wherein the well layer comprises well layers,
the barrier layer comprises barrier layers, and
the well layers and the barrier layers are alternately provided.
